(19) United States
(12) Patent Application Publication
(10) Pub. No.: US 2023/0042301 A1
(43) Pub. Date: Feb. 9, 2023

(54) SEMICONDUCTOR DEVICE

(71) Applicant: Sumitomo Electric Industries, Ltd., Osaka (JP)

(72) Inventor: Taizo TATSUMI, Osaka-shi (JP)

(73) Assignee: Sumitomo Electric Industries, Ltd., Osaka (JP)

(21) Appl. No.: 17/839,895

(22) Filed: Jun. 14, 2022

(30) Foreign Application Priority Data
Aug. 4, 2021 (JP) 2021-128421

(51) Int. Cl. H03F 3/24; H03F 1/56; H03F 3/195; H01L 23/66

(52) U.S. Cl. CPC H03F 3/245; H01L 23/66; H03F 1/56; H03F 3/195; H01L 2223/6611; H01L 2223/6655

(57) ABSTRACT

A semiconductor device includes a substrate, an active region provided in the substrate, a plurality of gate fingers provided on the active region, extending in an extension direction, and arranged in an arrangement direction orthogonal to the extension direction, and a gate connection wiring commonly connected to the plurality of gate fingers and provided between the plurality of gate fingers and a first side surface of the substrate, wherein when viewed from the arrangement direction, a first position where a first end of a first gate finger as a part of the plurality of gate fingers is connected to the gate connection wiring is closer to the first side surface than a second position where a first end of a second gate finger as another part of the plurality of gate fingers is connected to the gate connection wiring.

### CROSS REFERENCE TO RELATED APPLICATIONS

This application claims priority based on Japanese Patent Application No. 2021-128421 filed on Aug. 4, 2021, and the entire contents of the Japanese patent applications are incorporated herein by reference.

### FIELD

The present disclosure relates to a semiconductor device, for example, a semiconductor device having a field effect transistor.

### BACKGROUND

A field effect transistor (FET: Field Effect Transistor) such as a GaN HEMT (Gallium Nitride High Electron Mobility Transistor) is used as a high frequency power amplifier for a base station. It is known that the layout of the FET is a multi-finger type (for example, U.S. Unexamined Patent Application Publication No. 2020/0127627, and U.S. Patent No. 10381984). A method for calculating a thermal resistance of the GaN HEMT is known (for example, Non-Patent Document 1: K. Ohgami et al. "Transient Thermal Response Impact of 3.5 GHz GaN HEMT Amplifier on TDD LTE Spectrum and its Improvement Based on a Thermal Equivalent Circuit Approach" IEEE Symposium on Compound Semiconductor Integrated Circuit (2016)). Note that the technique related to the present disclosure is disclosed in Japanese Laid-open Patent Publications No. 2014-171971, No. 2007-141971, No. 2009-277877, and No. 2019-92009.

### SUMMARY

A semiconductor device according to the present disclosure includes: a substrate; an active region provided in the substrate; a plurality of gate fingers provided on the active region, extending in an extension direction, and arranged in an arrangement direction orthogonal to the extension direction; and a gate connection wiring commonly connected to the plurality of gate fingers and provided between the plurality of gate fingers and a first side surface of the substrate; wherein when viewed from the arrangement direction, a first position where a first end of a first gate finger as a part of the plurality of gate fingers is connected to the gate connection wiring is closer to the first side surface than a second position where a first end of a second gate finger as another part of the plurality of gate fingers is connected to the gate connection wiring.

### BRIEF DESCRIPTION OF DRAWINGS

FIG. 1 is a block diagram illustrating an amplifier according to a first embodiment.

FIG. 2 is a plan view illustrating the amplifier according to the first embodiment.

FIG. 3 is a plan view illustrating a semiconductor chip according to the first embodiment.

FIG. 4 is a cross-sectional view taken along line A-A of FIG. 3.

FIG. 5 is a plan view illustrating a semiconductor chip according to first comparative example.

FIG. 6 is a cross-sectional view taken along line A-A of FIG. 5.

FIG. 7 is a cross-sectional view taken along line B-B of FIG. 3.

FIG. 8 is a cross-sectional view taken along line C-C of FIG. 3.

FIG. 9 is a cross-sectional view taken along line D-D of FIG. 3.

FIG. 10 is a plan view illustrating a semiconductor chip according to a second embodiment.

FIG. 11 is a cross-sectional view taken along line A-A of FIG. 10.

FIG. 12 is a plan view illustrating a semiconductor chip according to a third embodiment.

FIG. 13 is a plan view illustrating a semiconductor chip according to a fourth embodiment.

### DETAILED DESCRIPTION OF EMBODIMENTS

In a multi-finger type FET, increasing the heat dissipation increases the chip size, and decreasing the chip size decreases the heat dissipation.

The present disclosure has been made in view of the above problems, and an object of the present disclosure is to provide a semiconductor device having high heat dissipation.

### Description of Embodiments of the Present Disclosure

First, the contents of the embodiments of this disclosure are listed and explained.

A semiconductor device according to the present disclosure includes: a substrate; an active region provided in the substrate; a plurality of gate fingers provided on the active region, extending in an extension direction, and arranged in an arrangement direction orthogonal to the extension direction; and a gate connection wiring commonly connected to the plurality of gate fingers and provided between the plurality of gate fingers and a first side surface of the substrate; wherein when viewed from the arrangement direction, a first position where a first end of a first gate finger as a part of the plurality of gate fingers is connected to the gate connection wiring is closer to the first side surface than a second position where a first end of a second gate finger as another part of the plurality of gate fingers is connected to the gate connection wiring. Thereby, the heat dissipation can be improved.

At least a part of first regions where first bonding wires are connected to the gate connection wiring may overlap with a region between the first position and the second position, viewed from the arrangement direction.

The semiconductor device further may include: a plurality of source fingers provided on the active region, extending in the extension direction and arranged in the arrangement direction; a plurality of drain fingers provided on the active region, extending in the extension direction, and alternately provided with the plurality of source fingers in the arrangement direction; and a drain connection wiring commonly connected to first ends of the plurality of drain fingers, and provided between the plurality of gate fingers and a second side surface opposite to the first side surface of the substrate. Each of the plurality of gate fingers may be sandwiched between one of the plurality of source fingers and one of the plurality of drain fingers in the arrangement direction.

When viewed from the arrangement direction, a third position at which a second end of the first gate finger near the drain connection wiring is located may be different from a fourth position at which a second end of the second gate finger near the drain connection wiring is located, and at least a part of second regions where second bonding wires are connected to the drain connection wiring may overlap with a region between the third position and the fourth position, viewed from the arrangement direction.

When viewed from the arrangement direction, a third position at which a second end of the first gate finger near the drain connection wiring is located may be different from a fourth position at which a second end of the second gate finger near the drain connection wiring is located, and a number of first bonding wires connected to the gate connection wiring may be less than a number of second bonding wires connected to the drain connection wiring.

A thickness of the substrate may be ½ or more of a shortest distance in the arrangement direction between adjacent gate fingers among the plurality of gate fingers.

The semiconductor device further may include a base substrate; and a bonding material that bonds the base substrate to a lower surface of the substrate. A distance between the first position and the first side surface may be smaller than the thickness of the substrate, and the bonding material may cover a region between a position of the first side surface separated from an upper end of the substrate toward a lower end by the distance and a lower end of the first side surface.

A third region provided with one or more of the first gate fingers without sandwiching another gate finger therebetween and a fourth region provided with one or more of the second gate fingers without sandwiching another gate finger therebetween may be provided alternately in the arrangement direction.

The substrate may include a SiC substrate.

### Details of Embodiments of the Present Disclosure

Specific examples of a semiconductor device in accordance with embodiments of the present disclosure are described below with reference to the drawings. The present disclosure is not limited to these examples, but is indicated by the claims, which are intended to include all modifications within the meaning and scope of the claims.

### First Embodiment

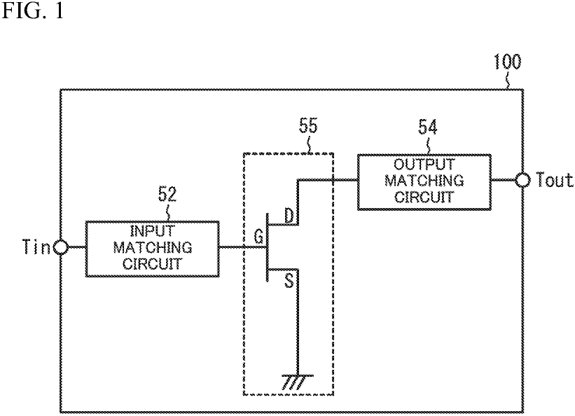

FIG. 1 is a block diagram illustrating an amplifier according to a first embodiment. As illustrated in FIG. 1, an amplifier 100 includes an FET 55, an input matching circuit 52, and an output matching circuit 54. A source S of the FET 55 is connected to a ground. A high frequency signal input from an input terminal Tin is input to a gate G of the FET 55 via the input matching circuit 52. The high frequency signal amplified by the FET 55 is output from an output terminal Tout via the output matching circuit 54. The input matching circuit 52 matches an input impedance of the input terminal Tin with an impedance of the gate G of the FET 55. The output matching circuit 54 matches an output impedance of the output terminal Tout with an impedance of a drain D of the FET 55. The amplifier 100 is, for example, a power amplifier (power amplifier) for wireless communication for 0.5 GHz to 10 GHz (for example, 3.9 GHz). An output power of the amplifier 100 is, for example, 30 dBm to 40 dBm, and a drain efficiency is, for example, 50% to 70%. When the drain efficiency is 50%, a power consumption is almost the same as the output power, and is 1W to 10W. The power consumption of the amplifier 100 is almost the power consumption of the FET 55.

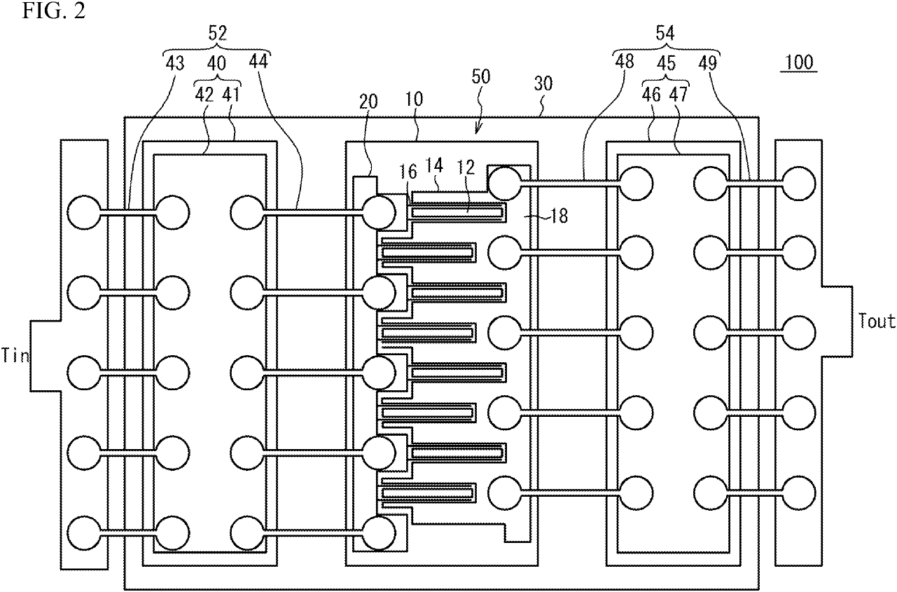

FIG. 2 is a plan view illustrating the amplifier according to the first embodiment. A semiconductor chip 50 and matching components 40 and 45 are mounted on a base substrate 30. The base substrate 30 is a conductive substrate. The semiconductor chip 50 includes a substrate 10, and source fingers 12, drain fingers 14, gate fingers 16, a drain connection wiring 18, and a gate connection wiring 20 provided on the substrate 10. The matching components 40 and 45 are, for example, capacitive components. The matching component 40 includes a dielectric substrate 41 and an electrode 42 provided on the dielectric substrate 41. The matching component 45 includes a dielectric substrate 46 and an electrode 47 provided on the dielectric substrate 41.

The input terminal Tin and the output terminal Tout are provided on, for example, an insulating frame body provided on the base substrate 30, and are electrically separated from the base substrate 30. The input terminal Tin and the electrode 42 are connected by bonding wires 43, and the electrode 42 and the gate connection wiring 20 are connected by bonding wires 44. The drain connection wiring 18 and the electrode 47 are connected by bonding wires 48. The electrode 47 and the output terminal Tout are connected by bonding wires 49. The bonding wires 43 and 44 and the matching component 40 form the input matching circuit 52. The bonding wires 48 and 49 and the matching component 45 form the output matching circuit 54.

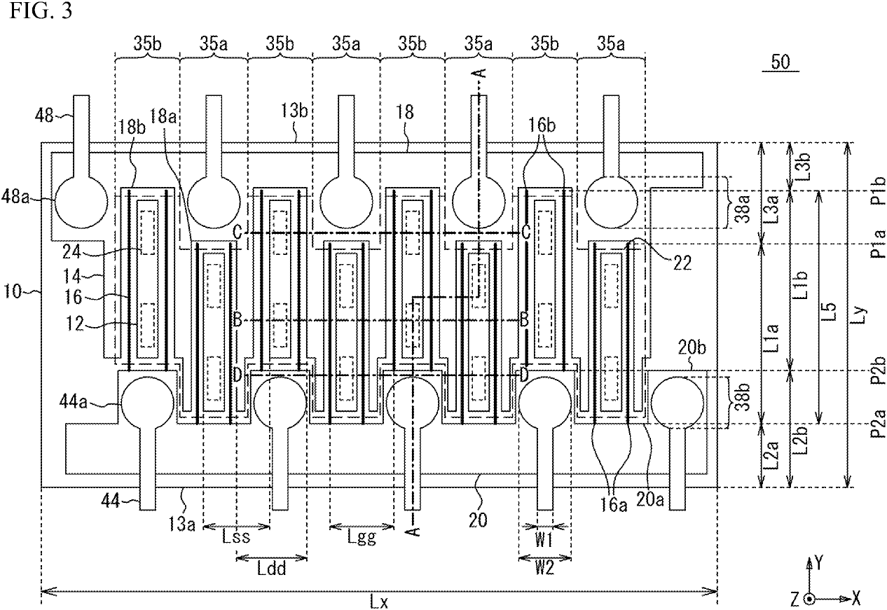

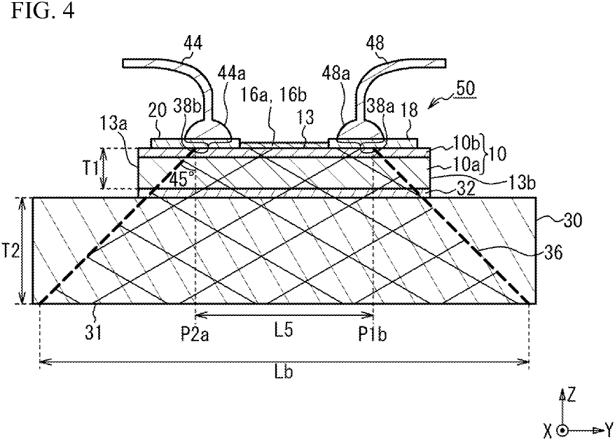

FIG. 3 is a plan view illustrating a semiconductor chip according to the first embodiment. FIG. 4 is a cross-sectional view taken along line A-A of FIG. 3. An arrangement direction of the plurality of gate fingers 16 is an X direction, an extension direction is a Y direction, and a normal direction of the substrate 10 is a Z direction. The X, Y and Z directions are orthogonal to each other. As illustrated in FIGS. 3 and 4, the semiconductor chip 50 is bonded to the base substrate 30 by a bonding material 32. The substrate 10 is provided with a substrate 10a and a semiconductor layer 10b. The base substrate 30 is, for example, a copper substrate, and a thickness T2 is, for example, 100 µm to 500 µm. The bonding material 32 is a conductive layer obtained by sintering a metal paste such as a silver paste, and is a conductive layer obtained by sintering a nanosilver paste having nanosilver particles having a particle diameter of, for example, 10 nm to 100 nm. When the FET 55 is a GaN HEMT, the substrate 10a is, for example, a SiC substrate or a diamond substrate. The semiconductor layer 10b is a nitride semiconductor layer, and includes a GaN channel layer and an AlGaN barrier layer from a position close to the substrate 10a. The thickness T1 of the substrate 10 is, for example, 50 µm to 200 µm. The thickness of the semiconductor layer 10b is sufficiently thinner than the thickness of the substrate 10a, for example, several µm or less. Therefore, the thickness T1 of the substrate 10 is almost the thickness of the substrate 10a.

The source fingers 12 and the drain fingers 14 are alternately arranged in the X direction on the substrate 10. The gate finger 16 is provided between the source finger 12 and the drain finger 14. The source finger 12 is electrically connected to the base substrate 30 by through electrodes 24 penetrating the substrate 10 and is short-circuited. The plurality of drain fingers 14 are commonly connected to the drain connection wiring 18 at a +Y end. The plurality of gate fingers 16 are commonly connected to the gate connection wiring 20 at a -Y end. The drain connection wiring 18 is provided between the gate finger 16 and a second side surface 13b (i.e., a side surface opposite to a first side surface 13a) of the substrate 10. The gate connection wiring 20 is provided between the gate finger 16 and the first side surface 13a of the substrate 10. The source fingers 12, the drain fingers 14, and the gate fingers 16 are provided on an active region 22. The active region 22 is a region in which the semiconductor layer 10b is activated. A region outside the active region 22 is an inactive region. The drain connection wiring 18 and the gate connection wiring 20 are provided on the inactive region.

Regions 35a and 35b are alternately provided on an upper surface 13 of the substrate 10 in the X direction. The source fingers 12, the drain fingers 14, the gate fingers 16, and the active region 22 are shifted in the -Y direction in the region 35a and in the +Y direction in the region 35b. The gate fingers 16 provided in the regions 35a and 35b are referred to as gate fingers 16a and 16b, respectively. The drain connection wiring 18 includes protrusions 18a protruding in the -Y direction in the region 35a and recesses 18b recessed in the +Y direction in the region 35b. The gate connection wiring 20 includes recesses 20a recessed in the -Y direction in the region 35a, and protrusions 20b protruding in the +Y direction in the region 35b. Balls 48a of the bonding wire 48 are bonded to the protrusions 18a, and balls 44a of the bonding wire 44 are bonded to the protrusions 20b. At least a part of regions 38a where the balls 48a bond to the protrusions 18a is located between positions P1a and P1b. At least a part of regions 38b where the balls 44a bond to the protrusions 20b is located between positions P2a and P2b.

Pitches of the source finger 12 and the drain finger 14 in the X direction are indicated as Lss and Ldd, respectively. A pitch of two gate fingers 16 is indicated as Lgg. Lss, Ldd and Lgg are uniform in, for example, the X and Y directions. When the adjacent gate fingers 16 are the gate fingers 16a, respective intervals between the adjacent gate fingers 16a are the same as each other in the plurality of regions 35a. When the adjacent gate fingers 16 are the gate fingers 16b, respective intervals between the adjacent gate fingers 16b are the same as each other in the plurality of regions 35b. When the adjacent gate fingers 16 are the gate fingers 16a and 16b, an interval between the adjacent gate fingers 16a and 16b may be the same as or different from the interval between the adjacent gate fingers 16a and the interval between the adjacent gate fingers 16b. Lss, Ldd and Lgg are, for example, 50 µm to 300 µm. The lengths of the substrate 10 in the X and Y directions are Lx and Ly. Lx is, for example, 300 µm to 10000 µm, and Ly is, for example, 300 µm to 2000 µm. A length of the gate finger 16a in the region 35a is indicated as L1a. A position where the gate finger 16a is connected to the gate connection wiring 20 is indicated as P2a. A position of the +Y end of the gate finger 16a is indicated as P1a. A length in the Y direction between the side surface 13a on the -Y side of the substrate 10 and the position P2a is indicated as L2a. A length in the Y direction between the side surface 13b on the +Y side of the substrate 10 and the position P1a is indicated as L3a. A length of the gate finger 16b in the region 35b is indicated as L1b. A position where the gate finger 16b is connected to the gate connection wiring 20 is indicated as P2b. A position of the +Y end of the gate finger 16b is indicated as P1b. A length in the Y direction between the side surface 13a on the -Y side of the substrate 10 and the position P2b is indicated as L2b. A length in the Y direction between the side surface 13b on the +Y side of the substrate 10 and the position P1b is indicated as L3b. A distance between the positions P2a and P1b is indicated as L5. The lengths L1a and L1b are, for example, 100 µm to 1800 µm.

The source finger 12 and the drain finger 14 are metal layers, for example, aluminum wirings, copper wirings or gold wirings. The gate fingers 16a and 16b are metal layers, for example, gold layers. The drain connection wiring 18 and the gate connection wiring 20 are, for example, metal layers made of gold layers. The bonding wires 44 and 48 are metal wires such as gold wires. A diameter W1 of each of the bonding wires 44 and 48 is, for example, 20 µm to 50 µm, and the numbers of bonding wires 44 and 48 are appropriately set by values of the current flowing through the bonding wires 44 and 48, respectively. A width W2 (diameter) of each of the balls 44a and 48a is, for example, 80 µm to 100 µm.

### First Comparative Example

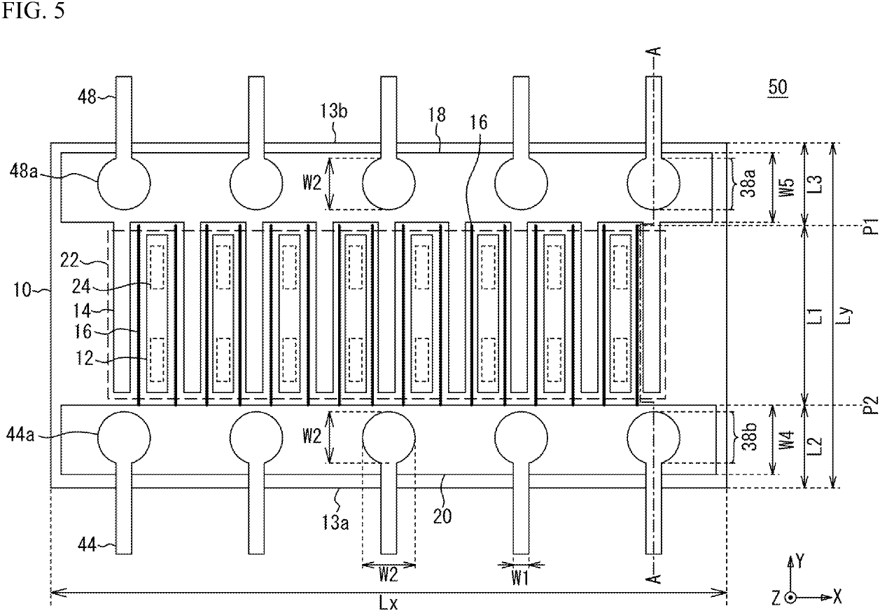

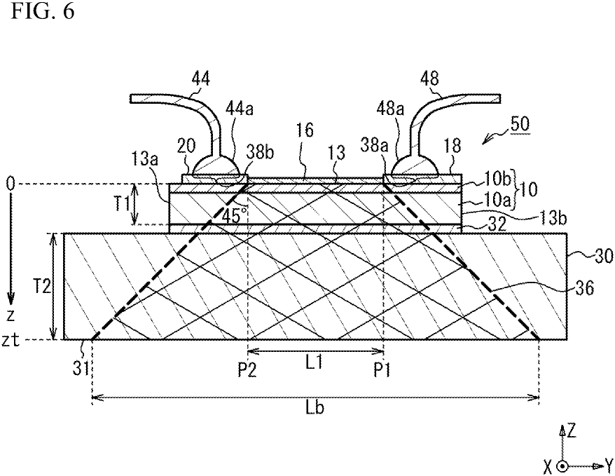

FIG. 5 is a plan view illustrating a semiconductor chip according to first comparative example. FIG. 6 is a cross-sectional view taken along line A-A of FIG. 5. As illustrated in FIGS. 5 and 6, in the first comparative example, the positions of the source finger 12, the drain finger 14, and the gate finger 16 in the Y direction are the same as each other, unlike the first embodiment. The drain connection wiring 18 and the gate connection wiring 20 are not provided with the protrusions 18a and 20b, and the recesses 18b and 20a. The widths W5 and W4 of the drain connection wiring 18 and the gate connection wiring 20 in the Y direction are larger than the width W2 of the balls 44a and 48a in the Y direction. For example, when the width W2 is 100 µm, the widths W4 and W5 are larger than 100 µm. Considering margins between the side surfaces 13a and 13b of the substrate 10 and the gate connection wiring 20 and the drain connection wiring 18, a distance L2 between the side surface 13a and the position P2 where the gate finger 16 is connected to the gate connection wiring 20 is, for example, 150 µm, and a length L3 between the +Y end of the gate finger 16 and the side surface 13b is, for example, 150 µm. Assuming that the length L1 of the gate finger 16 is, for example, 400 µm, a length Ly of the substrate 10 in the Y direction is, for example, 700 µm. In the first comparative example, the regions 38a and 38b where the balls 44a and 48a bond to the gate connection wiring 20 and the drain connection wiring 18, respectively, are not located between the positions P1 and P2.

A region where heat is generated in the semiconductor chip 50 is near the maximum electric field in the channel layer in the semiconductor layer 10b. The heat generation region is in the vicinity of the upper surface 13 of the substrate 10 in the cross section of FIG. 6, and is substantially the same as a region where the gate finger 16 overlaps with the active region 22 in the plane of FIG. 5. A distance between the position P2 where the gate finger 16 is connected to the gate connection wiring 20 and the -Y end of a region where the gate finger 16 overlaps with the active region 22 is sufficiently shorter than the length L1 of the gate finger 16. Further, a distance between a position P1 of the +Y end of the gate finger 16 and the +Y end of the region where the gate finger 16 overlaps with the active region 22 is sufficiently shorter than the length L1 of the gate finger 16. Therefore, the heat generation region can be regarded as the gate finger 16 (that is, a gate finger between the positions P1 and P2).

When a SiC substrate is used as the substrate 10a and a copper substrate is used as the base substrate 30, the thermal conductivity of SiC and copper is 400 to 450 W/(K·m) and 390 W/(K·m), respectively, which are almost the same as each other. As described in Non-Patent Document 1, a heat flow path 36 from the gate finger 16 to the base substrate 30 via the substrate 10 expands from the gate finger 16 toward the -Z direction. A spread angle of the heat flow path 36 with respect to the -Z direction is 45°. A lower surface 31 of the base substrate 30 is a heat dissipation surface through which heat is dissipated. The lower surface 31 is thermally connected to a hot bath such as a housing or a heat sink. The length Lb of the heat flow path 36 on the lower surface 31 is Lb = L1 + 2 x (T1 + T2). In the case of T1 = 100 µm and T2 = 300 µm, Lb is 1200 µm. It is assumed that the z coordinate of the upper surface 13 of the substrate 10 is 0, the -Z direction is z, and the z of the lower surface 31 of the base substrate 30 is zt. Assuming that an area of the XY plane of the heat flow path 36 in z is S(z) and the thermal conductivity of the substrate 10 and the base substrate 30 is λ m, a thermal resistance Rth from the gate finger 16 provided on the upper surface 13 of the substrate 10 to the lower surface 31 is given by formula 1. (Formula 1)

$${R}_{t h} = {\int }_{0}^{z t} \frac{1}{s \left(z\right) \times λ m} d z$$

When the thermal resistance Rth is high, the heat generated in the vicinity of the gate finger 16 is not released, and the temperature in the active region 22 in the vicinity of the gate finger 16 increases. This causes a decrease in FET characteristics and a decrease in FET life. In order to suppress the increase in temperature near the gate finger 16, the density of the gate finger 16 needs to be lowered, and a chip area of the semiconductor chip 50 becomes large.

### Heat Flow Path in First Embodiment

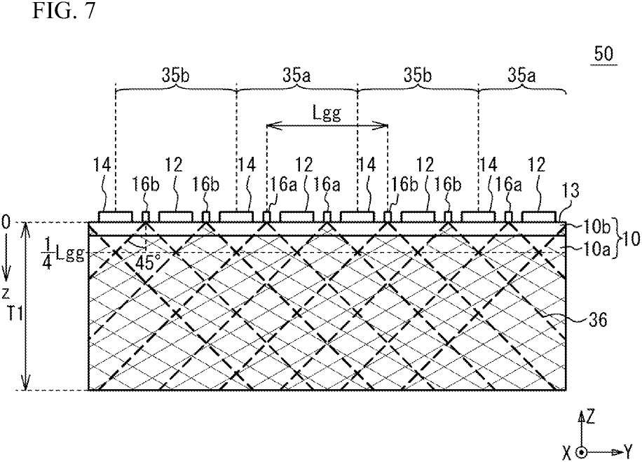

FIGS. 7 to 9 are cross-sectional views taken along lines B-B, C—C and D-D of FIG. 3. Respectively. As illustrated in FIG. 7, in the B-B cross section of the first embodiment, a pitch of the arrangement between the gate fingers 16a and 16b is Lgg/2. The heat flow path 36 extends from the gate fingers 16a and 16b toward the -Z direction. The spread angle of the heat flow path 36 with respect to the -Z direction is 45°. When the position z from the upper surface 13 of the substrate 10 is about Lgg/4 or more, the heat flow paths 36 extending from the adjacent gate fingers 16a and 16b overlap with each other, and the area S(z) becomes large.

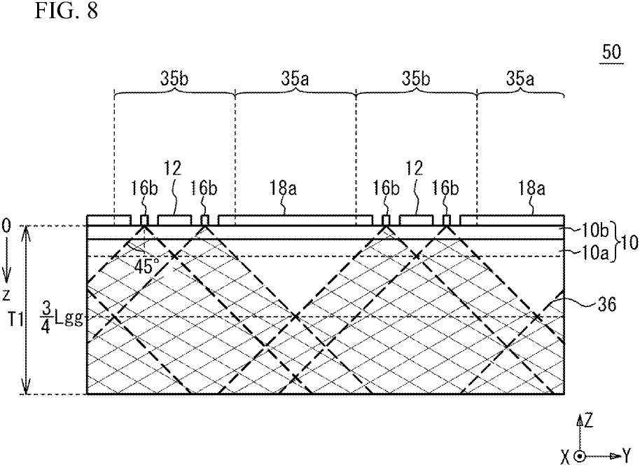

As illustrated in FIG. 8, in the C-C cross section, the gate finger 16a is not provided in the region 35a, but the protrusion 18a of the drain connection wiring 18 is provided in the region 35a. The heat flow paths 36 extending from the gate fingers 16b adjacent via the protrusion 18a extend below the protrusion 18a. Thereby, the area S(z) at the same position z becomes larger in the first embodiment than in the first comparative example. In particular, when the position z is about ¾ Lgg or more, the heat flow paths 36 extending from the gate fingers 16b adjacent via the protrusion 18a overlap with each other, and the area S(z) becomes larger.

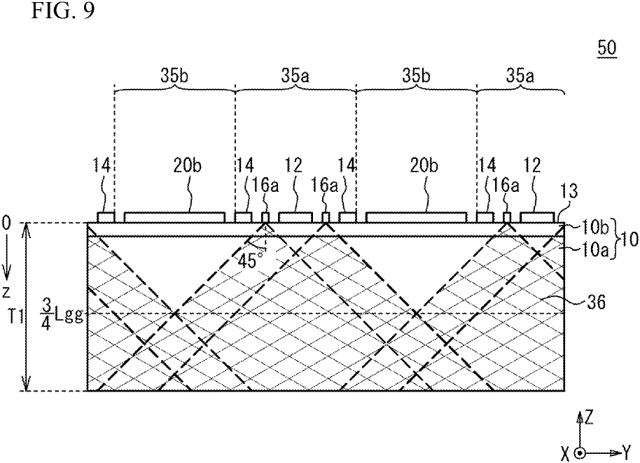

As illustrated in FIG. 9, in the D-D cross section, the gate finger 16b is not provided in the region 35b, but the protrusion 20b of the gate connection wiring 20 is provided in the region 35b. The heat flow paths 36 extending from the gate fingers 16a adjacent via the protrusion 20b extend below the protrusion 20b. Thereby, the area S(z) at the same position z becomes larger in the first embodiment than in the first comparative example. In particular, when the position z is about ¾ Lgg or more, the heat flow paths 36 extending from the gate fingers 16b adjacent via the protrusion 20b overlap with each other, and the area S(z) becomes larger.

As described above, since the area S(z) at the same position z becomes larger in the first embodiment than in the first comparative example, the thermal resistance Rth can be lowered. If ¾ Lgg is sufficiently smaller than T1+T2, the heat flow paths 36 can be regarded as extending toward the -Y side and the +Y side at an angle of 45° from the position P2a at the -Y end of the gate finger 16a and the position P1b at the +Y end of the gate finger 16b toward the -Z direction, respectively, as illustrated in FIG. 4. When the distance L5 between the positions P2a and P1b is 500 µm, the length Lb of the heat flow path 36 on the lower surface 31 is 1300 µm. As compared with the first comparative example, the length of the heat flow path 36 on the upper surface 13 of the substrate 10 is 1.25 times (L5/L1 = 500/400), and the length Lb of the heat flow path 36 on the lower surface 31 is 1.08 times (1300/1200). Thus, the area S(z) at each position z is larger and the thermal resistance Rth is lower in the first embodiment than in the first comparative example. Thereby, the increase in temperature of the gate fingers 16a and 16b can be suppressed.

When the lengths L2a and L3b in FIG. 3 are 100 µm and the lengths L2b and L3a are 200 µm, the length Ly of the substrate 10 in the X direction is 700 µm, which can be the same as that of the first comparative example. The bonding wire 48 is bonded to the protrusion 18a of the region 35a, and the bonding wire 44 is bonded to the protrusion 20b of the region 35b. That is, at least a part of the regions 38a is located between the positions P1a and P1b, and at least a part of the regions 38b is located between the positions P2a and P2b. Thereby, the lengths L3a and L2b can be secured by 200 µm as the region for bonding the balls 48a and 44a. Thus, in the first embodiment, the size of the semiconductor chip 50 is the same as that of the first comparative example, and the heat dissipation from the FET can be improved. In the first embodiment, the size of the semiconductor chip 50 can be reduced as long as the heat dissipation in the first embodiment is the same as that in the first comparative example. Thus, in the first embodiment, the heat dissipation can be improved and the size can be reduced.

### Second Embodiment

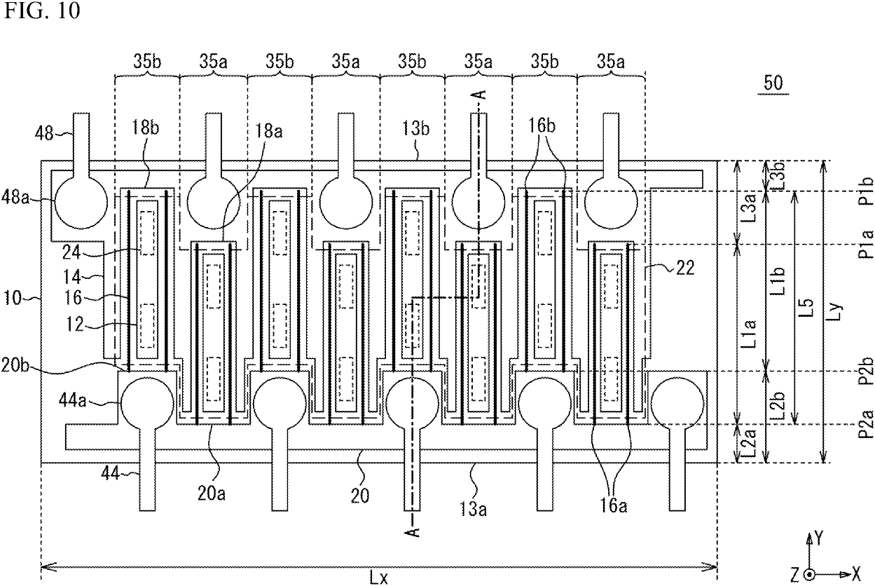

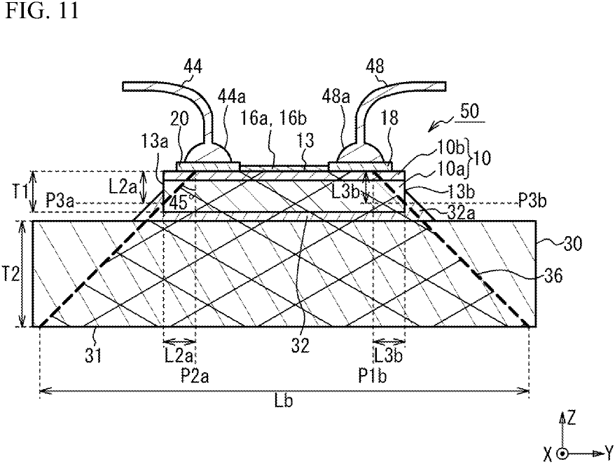

FIG. 10 is a plan view illustrating a semiconductor chip according to a second embodiment. FIG. 11 is a cross-sectional view taken along line A-A of FIG. 10. As illustrated in FIGS. 10 and 11, in the second embodiment, the lengths L2a and L3b are set to, for example, 70 µm, and the lengths L2b and L3a are set to 170 µm. The lengths L1b and L1a are set to 400 µm. If the balls 44a and 48a are 100 µm, the lengths L1b and L2a of 170 µm are sufficient. This allows a length Ly of the substrate 10 in the y direction to be 640 µm. However, if the lengths L2a and L3b are short, the heat flow path 36 protrudes from the side surfaces 13a and 13b of the substrate 10. Therefore, a bonding material 32a is provided at a lower part of the side surfaces 13a and 13b of the substrate 10. When the nanosilver paste is used as the bonding material 32a, the thermal conductivity of the bonding material 32a in which the nano-silver paste is sintered is 200 to 300 W/(K·m), which is as high as that of SiC and copper. Thereby, the heat flow passes through the bonding material 32a, so that the same level of the thermal resistance as in the first embodiment can be obtained. Moreover, the chip area can be reduced.

When the length L2a is shorter than the thickness T1 of the substrate 10, the heat flow path 36 protrudes from the side surface 13a of the substrate 10. A position where the heat flow path 36 protrudes from the side surface 13a is a position P3a separated from the upper surface 13 of the substrate 10 by the length L2a in the -Z direction. Therefore, a range in which the bonding material 32a is in contact with the side surface 13a of the substrate 10 preferably includes the position P3a. When the length L3b is shorter than the thickness T1, a range in which the bonding material 32a is in contact with the side surface 13b of the substrate 10 preferably includes a position P3b separated from the upper surface 13 of the substrate 10 by the length L3b in the -Z direction.

### Third Embodiment

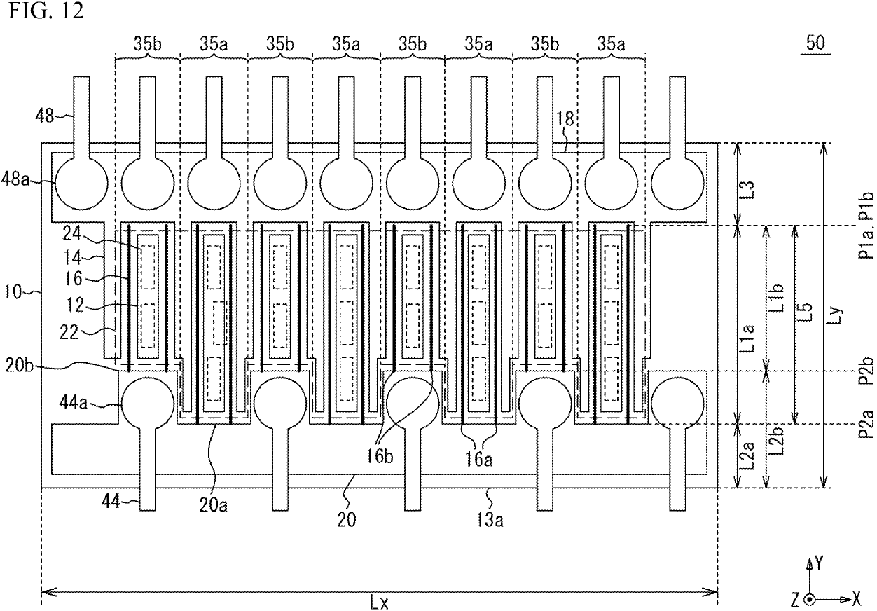

FIG. 12 is a plan view illustrating a semiconductor chip according to a third embodiment. As illustrated in FIG. 12, the gate connection wiring 20 is provided with the protrusions 20b and the recesses 20a, but the drain connection wiring 18 is not provided with the protrusions and the recesses. The position P2a is located on the -Y side of the position P2b. The positions P1a and P1b are substantially the same in the Y direction. The bonding wire 48 is provided about twice as many as the bonding wire 44.

The lengths L1a and L1b of the gate fingers 16a and 16b are, for example, 440 µm and 360 µm, respectively. The lengths L2a and L2b are, for example, 70 µm and 150 µm, respectively. The length L3 is, for example, 150 µm. The length Ly of the substrate 10 in the Y direction is 660 µm. The distance L5 between the positions P2a and P1b is 440 µm, and the length Lb of the heat flow path on the lower surface 31 of the base substrate 30 is 1240 µm. Other configurations are the same as those in the second embodiment, and the description thereof will be omitted.

The thermal resistance in the third embodiment becomes larger than those in the first and the second embodiments. An output current of the amplifier 55 is 2 to 5 times an input current. The number of the bonding wires 44 and 48 is set so that a value of the current flowing through the bonding wires 44 and 48 per one is equal to or less than an allowable current value. In this case, the number of the bonding wires 44 can be ½ to ⅕ of the number of the bonding wires 48. In the third embodiment, a ratio of the number of bonding wires 44 and 48 can be close to a ratio of the input current and the output current.

### Fourth Embodiment

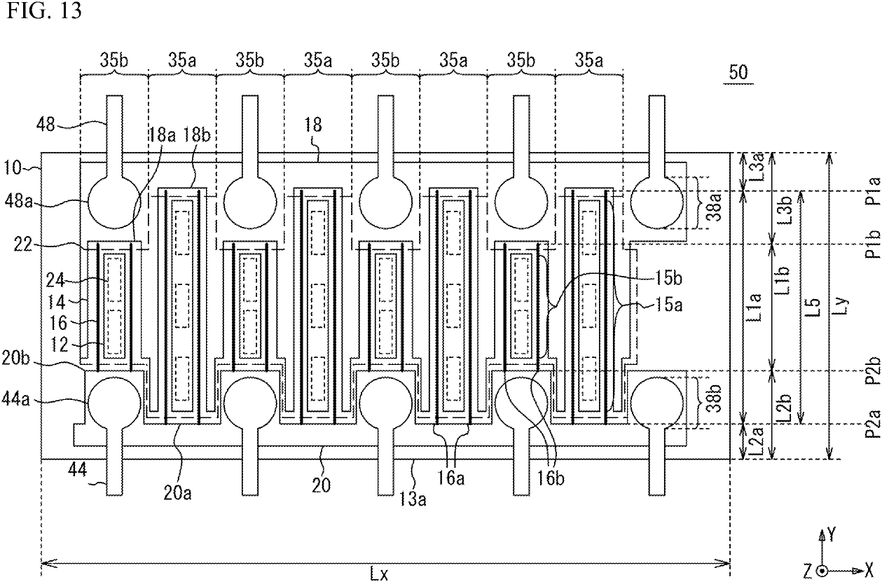

FIG. 13 is a plan view illustrating a semiconductor chip according to a fourth embodiment. As illustrated in FIG. 13, the recesses 18b and 20a are provided in the regions 35a, and the protrusions 18a and 20b are provided in the regions 35b. The position P2a is located on the -Y side of the position P2b, and the position P1a is located on the +Y side of the position P1b. Thereby, the length L1a of the gate finger 16a is longer than the length L1b of the gate finger 16b. The lengths L1a and L1b are, for example, 500 µm and 300 µm, respectively. Other configurations are the same as those in the second embodiment, and the description thereof will be omitted. In the fourth embodiment as well, the thermal resistance can be lowered as in the second embodiment.

According to the first to fourth embodiments, when viewed from the X direction, the first position P2a where the first end of the first gate finger 16a as a part of the plurality of gate fingers 16 is connected to the gate connection wiring 20 is located closer to the first side surface 13a of the substrate 10 than the second position P2b where the first end of the second gate finger 16b as another part of the plurality of gate fingers 16 is connected to the gate connection wiring 20. Thereby, as illustrated in FIG. 9, the heat flow path 36 becomes wider between the positions P2a and P2b, and the thermal resistance from the gate finger 16 to the lower surface 31 of the base substrate 30 can be lowered. Therefore, the heat dissipation can be improved. In order to further improve the heat dissipation, the distance between the positions P2a and P2b is preferably 0.05 times or more, more preferably 0.1 or more the length in the Y direction of the plurality of shortest gate fingers 16.

At least a part of the first regions 38b to which the bonding wires 44 (first bonding wire) are connected to the gate connection wiring 20 overlaps with a region between the positions P2a and P2b when viewed from the X direction. Thereby, the length L2a can be shortened and the semiconductor chip 50 can be reduced in size. When viewed from the X direction, the first region 38b preferably overlaps with 50% or more the region between the positions P2a and P2b.

The plurality of source fingers 12 and the plurality of drain fingers 14 are provided alternately, and each of the plurality of gate fingers 16 is sandwiched between one of the plurality of source fingers 12 and one of the plurality of drain fingers 14 in the X direction. This makes it possible to realize the multi-finger type FET.

When viewed from the X direction, the third position P1a where the second end of the gate finger 16a near the drain connection wiring 18 is located is different from the fourth position P1b where the second end of the gate finger 16b near the drain connection wiring 18 is located. At least a part of the second regions 38a to which the bonding wires 48 (second bonding wire) are connected to the drain connection wiring 18 overlaps with a region between the third position P1a and the fourth position P2b when viewed from the X direction. Thereby, the length L3a can be shortened and the semiconductor chip 50 can be reduced in size. When viewed from the X direction, the second region 38a preferably overlaps with 50% or more the region between the positions P1a and P1b.

As in the third embodiment, when viewed from the X direction, the third position P1a of the gate finger 16a and the fourth position P1b of the gate finger 16b are the same as each other. Thereby, the number of bonding wires 48 connected to the drain connection wiring 18 can be larger than the number of bonding wires 44 connected to the gate connection wiring 20. This can increase the number of bonding wires 48 through which the output current larger than the input current flows. The number of the bonding wires 48 is preferably 1.5 times or more, more preferably 2 times or more the number of the bonding wires 44.

As illustrated in FIG. 7, the thickness T1 of the substrate 10 is ½ or more of the shortest distance Lgg/2 in the X direction between the adjacent gate fingers 16 among the plurality of gate fingers 16. Thereby, the heat flow paths 36 from the adjacent gate fingers 16 overlap with each other in the substrate 10. Therefore, the heat dissipation can be further improved. Further, as illustrated in FIG. 9, the thickness T1 of the substrate 10 is preferably ¾ or more of the shortest distance Lgg/2 in the X direction between the adjacent gate fingers 16a. Thereby, the heat flow paths 36 from the gate fingers 16b sandwiching the protrusion 20b overlap with each other in the substrate 10. Therefore, the heat dissipation can be further improved. The thickness T1 of the substrate 10 is preferably 1 times or more, more preferably 2 times or more the shortest distance Lgg/2.

The semiconductor chip 50 includes the base substrate 30, and the bonding material 32 that bonds the base substrate 30 to the lower surface of the substrate 10. This spreads the heat flow path 36 into the base substrate 30. Therefore, even if the thickness T1 of the substrate 10 is thinner than Lgg/4, the heat flow paths 36 from the adjacent gate finger 16 overlap with each other in the base substrate 30. Therefore, the heat dissipation can be improved.

As illustrated in FIG. 11 of the second embodiment, a distance L2a between the first position P2a and the first side surface 13a is smaller than the thickness T1 of the substrate 10. In this case, the bonding material 32a covers a region between the position P3a of the side surface 13a separated from the upper end of the substrate 10 by the distance L2a and the lower end of the side surface 13a. Thereby, the heat flow path 36 can be spread in the bonding material 32a, and the heat dissipation can be improved.

In the case of GaN HEMT, a sapphire substrate, a silicon substrate, a GaN substrate, a diamond substrate, or the like can be used as the substrate 10a. The substrate 10 preferably includes a single crystal SiC substrate having high thermal conductivity in order to reduce the thermal resistance of the heat flow path 36. The thickness of the SiC substrate 10a is preferably 0.9 times or more, more preferably 0.95 times or more the thickness T1 of the substrate 10. Although the nitride semiconductor layer such as a GaN-based semiconductor layer is described as the example of the semiconductor layer 10b, the semiconductor layer 10b may be a GaAs-based semiconductor layer.

In the first to the fourth embodiments, two gate fingers 16a are provided in the single region 35a, and two gate fingers 16b are provided in the single region 35b. The number of gate fingers 16a provided in the single region 35a may be one or three or more. The number of gate fingers 16b provided in the single region 35b may be one or three or more. That is, one or more gate fingers 16a are provided in the region 35a (third region) without sandwiching another gate finger 16 therebetween. One or more gate fingers 16b are provided in the region 35b (fourth region) without sandwiching another gate finger 16 therebetween. The regions 35a and 35b are alternately provided in the X direction. Thereby, the heat dissipation can be improved in the multi-finger FET having a large output power. From the viewpoint of increasing the output power, the number of regions 35a and 35b is preferably 2 or more, and more preferably 3 or more.

When the number of gate fingers 16a per the single region 35a is large, the distance between the regions 35b becomes long in FIG. 8. Therefore, the position z where the heat flow paths 36 from the adjacent regions 35b overlap with each other becomes large. Therefore, S(z) in formula 1 does not increase, and hence the thermal resistance increases. The same applies when the number of gate fingers 16b per the single region 35b is large. Therefore, the number of gate fingers 16a provided in the single region 35a is preferably 4 or less, more preferably 3 or less, and further preferably 2 or less. The number of gate fingers 16b provided in the single region 35b is preferably 4 or less, more preferably 3 or less, and further preferably 2 or less.

The embodiments disclosed here should be considered illustrative in all respects and not restrictive. The present disclosure is not limited to the specific embodiments described above, but various variations and changes are possible within the scope of the gist of the present disclosure as described in the claims.

What is claimed is:

1. A semiconductor device comprising:
a substrate;
an active region provided in the substrate;
a plurality of gate fingers provided on the active region, extending in an extension direction, and arranged in an arrangement direction orthogonal to the extension direction; and
a gate connection wiring commonly connected to the plurality of gate fingers and provided between the plurality of gate fingers and a first side surface of the substrate;
wherein when viewed from the arrangement direction, a first position where a first end of a first gate finger as a part of the plurality of gate fingers is connected to the gate connection wiring is closer to the first side surface than a second position where a first end of a second gate finger as another part of the plurality of gate fingers is connected to the gate connection wiring.

2. The semiconductor device as claimed in claim 1, wherein
at least a part of first regions where first bonding wires are connected to the gate connection wiring overlaps with a region between the first position and the second position, viewed from the arrangement direction.

3. The semiconductor device as claimed in claim 1, further comprising:
a plurality of source fingers provided on the active region, extending in the extension direction and arranged in the arrangement direction;
a plurality of drain fingers provided on the active region, extending in the extension direction, and alternately provided with the plurality of source fingers in the arrangement direction; and
a drain connection wiring commonly connected to first ends of the plurality of drain fingers, and provided between the plurality of gate fingers and a second side surface opposite to the first side surface of the substrate;
wherein each of the plurality of gate fingers is sandwiched between one of the plurality of source fingers and one of the plurality of drain fingers in the arrangement direction.

4. The semiconductor device as claimed in claim 3, wherein
when viewed from the arrangement direction, a third position at which a second end of the first gate finger near the drain connection wiring is located is different from a fourth position at which a second end of the second gate finger near the drain connection wiring is located, and
at least a part of second regions where second bonding wires are connected to the drain connection wiring overlaps with a region between the third position and the fourth position, viewed from the arrangement direction.

5. The semiconductor device as claimed in claim 3, wherein
when viewed from the arrangement direction, a third position at which a second end of the first gate finger near the drain connection wiring is located is different from a fourth position at which a second end of the second gate finger near the drain connection wiring is located, and
a number of first bonding wires connected to the gate connection wiring is less than a number of second bonding wires connected to the drain connection wiring.

6. The semiconductor device as claimed in claim 1, wherein
a thickness of the substrate is ½ or more of a shortest distance in the arrangement direction between adjacent gate fingers among the plurality of gate fingers.

7. The semiconductor device as claimed in claim 6, further comprising:
a base substrate; and
a bonding material that bonds the base substrate to a lower surface of the substrate;
wherein a distance between the first position and the first side surface is smaller than the thickness of the substrate, and
the bonding material covers a region between a position of the first side surface separated from an upper end of the substrate toward a lower end by the distance and a lower end of the first side surface.

8. The semiconductor device as claimed in claim 1, wherein
a third region provided with one or more of the first gate fingers without sandwiching another gate finger therebetween and a fourth region provided with one or more of the second gate fingers without sandwiching another gate finger therebetween are provided alternately in the arrangement direction.

9. The semiconductor device as claimed in claim 1, wherein
the substrate includes a SiC substrate.
